(19) United States
(12) Patent Application Publication
(10) Pub. No.: US 2026/0180576 A1
(43) Pub. Date: Jun. 25, 2026

(54) SIGNAL ISOLATION CIRCUIT FOR TRANSFERRING MULTIPLE SIGNALS

(71) Applicant: KOREA ELECTROTECHNOLOGY RESEARCH INSTITUTE, Changwon-si (KR)

(72) Inventors: Ki Nam SONG, Changwon-si (KR); Ki Hyun KIM, Changwon-si (KR); In Ho KANG, Changwon-si (KR); Kyoung Ho LEE, Changwon-si (KR); Jong Hyun KIM, Changwon-si (KR)

(73) Assignee: KOREA ELECTROTECHNOLOGY RESEARCH INSTITUTE, Changwon-si (KR)

(21) Appl. No.: 19/539,334

(22) Filed: Feb. 13, 2026

Related U.S. Application Data
(63) Continuation of application No. PCT/KR2024/015859, filed on Oct. 18, 2024.

(30) Foreign Application Priority Data
Nov. 17, 2023 (KR) 10-2023-0159804

(51) Int. Cl. H03K 19/00; H02M 3/07; H03K 5/156

(52) U.S. Cl. CPC H03K 19/0016; H02M 3/07; H03K 5/1565

(57) ABSTRACT

A signal isolation circuit for transferring multiple signals is disclosed. The signal isolation circuit for transferring multiple signals from a first domain to a second domain includes a multi-signal encoder configured to encode first to third signals of the first domain into a single fourth signal, a transceiver configured to transfer the fourth signal from the first domain to the second domain; and a multi-signal decoder configured to decode the first to third signals from the fourth signal in the second domain.

### CROSS-REFERENCE TO RELATED APPLICATION

The present application is a continuation of International Application No. PCT/KR 2024/015859, filed Oct. 18, 2024, which is based upon and claims priority to Korean Patent Application No. 10-2023-0159804, filed on Nov. 17, 2023 in Korea. The entire disclosure of the above application is incorporated herein by reference.

### TECHNICAL FIELD

The present disclosure relates to a signal isolation circuit based on an on-off keying (OOK) signal transmission protocol.

### BACKGROUND

The content described below simply provides background information related to the present embodiment and does not constitute the prior art.

A signal isolation circuit refers to a circuit that transmits and receives data signals between two electrically isolated systems and mainly operates at different ground (GND) potentials. Such a signal isolation circuit requires an isolation channel that may provide electrical isolation, which is generally implemented using a micro-transformer, capacitors, magneto-resistors/giant magneto-resistors, or opto-electric devices.

On-off keying (OOK) is a signal protocol that uses digital states of signals transmitted through the isolation channel. For example, when a digital signal is high, the signal is transferred through the isolation channel, and when the digital signal is low, the signal is not transferred through the isolation channel. At this time, the digital signal is modulated into a high-frequency signal at the transmitter and transmitted through the isolation channel, and is then restored at the receiver through demodulation.

In the case of digital isolators and gate driver circuits that use the isolation channel, there are many instances in which two or more types of multiple signals need to be transferred. For example, a smart gate driver that includes a plurality of switching devices having a protection circuit operation function may transfer results of respective protection operations through the isolation channel. At this time, to utilize the OOK signal transmission protocol, a transceiver circuit consisting of a transmitter, a receiver, and an isolation barrier is required; however, a conventional transceiver circuit is able to transfer only one data signal in real-time, thus requiring as many isolation channels as the number of data signals to be transferred. Furthermore, although multiple signals may be transferred using a serializer and a de-serializer, this approach requires an oscillator and complex logic, which makes it unsuitable for gate driver circuit applications. Moreover, when an edge-triggered transceiver circuit is employed to minimize power consumption of the transceiver, two isolation channels are required to transfer a single signal. While the edge-triggering approach provides an advantage in terms of circuit simplicity, the edge-triggering approach increases the chip form factor of an integrated circuit, such as a smart gate driver or a digital isolator, that has to handle multiple signals and, consequently, increases manufacturing costs, thereby reducing product competitiveness.

### SUMMARY

At least one aspect of the present disclosure provides a signal isolation circuit for transferring multiple signals from a first domain to a second domain. The signal isolation circuit includes a multi-signal encoder configured to encode first to third signals of the first domain into a single fourth signal, wherein the multi-signal encoder is configured to adjust a pulse width of the fourth signal of the first domain based on the first and second signals of the first domain, and control whether to generate a pulse corresponding to the second signal of the first domain based on a third signal of the first domain; a transceiver configured to transfer the fourth signal from the first domain to the second domain; and a multi-signal decoder configured to decode the first to third signals from the fourth signal in the second domain, wherein the multi-signal decoder is configured to generate the first and second signals of the second domain based on a pulse width of the fourth signal of the second domain, and generate a third signal of the second domain based on a time interval between pulses of the fourth signal of the second domain

At least another aspect of the present disclosure provides a multi-signal encoder for encoding multiple input signals into a single output signal. The multi-signal encoder includes a pulse generator configured to generate, based on a first input signal, a first pulse signal having a first pulse width; a first pulse train generator configured to generate, based on a second input signal having a first logic level, a second pulse signal having a second pulse width different from the first pulse width, wherein the first pulse train generator is configured to be selectively disabled based on a logic level of a third input signal; a second pulse train generator configured to generate, based on the second input signal having a second logic level, a third pulse signal having a third pulse width different from the first and second pulse widths, wherein the second pulse train generator is configured to be selectively disabled based on a logic level of the third input signal; and a merging circuit configured to generate the output signal by merging the first, second, and third pulse signal

At least yet another aspect of the present disclosure provides a multi-signal decoder for decoding a single input signal into multiple output signals. The multi-signal decoder includes a first latch configured to generate a first output signal based on a time point when a first pulse having a length longer than a first threshold pulse width is detected in the input signal; a second latch configured to generate a second output signal based on both a time point when a second pulse having a length shorter than the first threshold pulse width and longer than a second threshold pulse width and a time point when a third pulse having a length shorter than the second threshold pulse width and longer than a third threshold pulse width are detected in the input signal; and a pulse detection circuit configured to generate a third output signal based on whether a subsequent pulse occurs within a predetermined threshold time from a time point when a preceding pulse occurs in the input signal.

In some embodiments, the pulse generator may the first pulse signal having a single pulse during a time interval in which the first signal of the first domain has a predetermined logic level. The first pulse train generator may generate the second pulse signal having one or more pulses according to a length of a time interval during which the second signal of the first domain has the first logic level. The second pulse train may generate generates the third pulse signal having one or more pulses according to a length of a time interval during which the second signal of the first domain has the second logic level. The second pulse width may be smaller than the first pulse width, and the third pulse width may be smaller than the second pulse width. The merging circuit may include a logic gate configured to merge the second pulse signal and the third pulse signal; and a multiplexer configured to output, as the fourth signal of the first domain, one of the first pulse signal and the merged signal based on the first pulse signal. The multi-signal encoder may further include an edge detection circuit configured to generate an edge detection signal by detecting rising and falling edges of the second signal of the first domain, and the merged signal may be masked by the edge detection signal.

In some embodiments, the first latch may receive, as a set input or a reset input, a first flag signal having an edge formed corresponding to the time point when the first pulse is detected. The second latch may receive, as either a set input or a reset input respectively, a second flag signal having an edge formed corresponding to the time point when the second pulse is detected and a third flag signal having an edge formed corresponding to the time point when the third pulse is detected. The multi-signal decoder may further include a charge pump circuit configured to convert the fourth signal of the second domain into a signal having a potential corresponding to a pulse width; and an analog-to-digital converter configured to generate one-hot codes by comparing the potential of the converted signal with a plurality of reference potentials. The first latch may receive the most significant bit of the one-hot code, and the second latch may receive remaining bits excluding the most significant bit. The analog-to-digital converter may include a plurality of comparators configured to generate a thermometer code by comparing a potential of the converted signal with each of the plurality of reference potentials; and a masking circuit configured to convert the thermometer code into the one-hot code.

In some embodiments, the first signal of the first domain may be a short-circuit protection signal (SCP) output from a short-circuit protection circuit provided in the first domain, the second signal of the first domain may be a signal obtained by pulse width modulation (PWM) based on a temperature detected from an external switching element, a module, or a printed circuit board (PCB), and the third signal of the first domain may be a power-supply-and-internal-temperature sensing signal (RDY) indicating whether a power supply and an internal temperature of the first domain are in a normal operation state.

### BRIEF DESCRIPTION OF THE DRAWINGS

FIG. 1 illustrates a configuration of a signal isolation circuit according to an embodiment of the present disclosure.

FIG. 2 illustrates a configuration of a multi-signal encoder according to an embodiment of the present disclosure.

FIG. 3 is a timing diagram illustrating an operation of a multi-signal encoder according to an embodiment of the present disclosure.

FIG. 4 illustrates a configuration of a multi-signal encoder according to another embodiment of the present disclosure.

FIG. 5 is a timing diagram illustrating an operation of a multi-signal encoder according to another embodiment of the present disclosure.

FIG. 6 illustrates a configuration of a multi-signal decoder according to an embodiment of the present disclosure.

FIG. 7 is a timing diagram illustrating an operation of a multi-signal decoder according to an embodiment of the present disclosure.

FIG. 8 illustrates a configuration of an analog-to-digital converter according to an embodiment of the present disclosure.

FIG. 9 illustrates a configuration of a pulse detection circuit according to an embodiment of the present disclosure.

FIG. 10 is a waveform diagram illustrating an operation of a pulse detection circuit according to an embodiment of the present disclosure.

FIG. 11 is a waveform diagram illustrating multiple input signals and multiple output signals of a signal isolation circuit according to an embodiment of the present disclosure.

### DETAILED DESCRIPTION

The present disclosure may provide a signal isolation circuit capable of transferring multiple signals through a single transceiver that includes a single isolation channel.

The features of the present disclosure are not limited to the aforementioned features, and other features not described above may be evidently understood by a person having ordinary skill in the art to which the present disclosure pertains from the following description.

Hereinafter, some exemplary embodiments of the present disclosure will be described in detail with reference to the accompanying drawings. In the following description, like reference numerals preferably designate like elements, although the elements are shown in different drawings. Further, in the following description of some embodiments, a detailed description of known functions and configurations incorporated therein will be omitted for the purpose of clarity and for brevity.

Additionally, various terms such as first, second, i), ii), a), b), etc., are used solely to differentiate one component from the other but not to imply or suggest the substances, order, or sequence of the components. Throughout this specification, when a part ‘includes’or ‘comprises’a component, the part is meant to further include other components, not to exclude thereof unless specifically stated to the contrary.

The description of the present disclosure to be presented below in conjunction with the accompanying drawings is intended to describe exemplary embodiments of the present disclosure and is not intended to represent the only embodiments in which the technical idea of the present disclosure may be practiced.

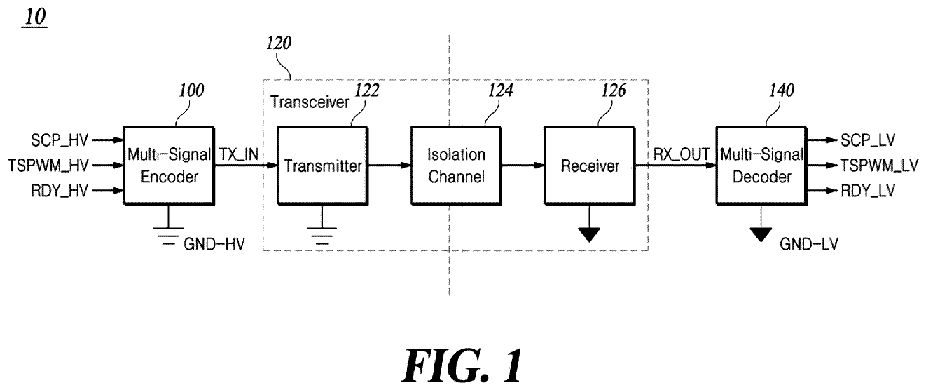

FIG. 1 illustrates a configuration of a signal isolation circuit according to an embodiment of the present disclosure.

The signal isolation circuit 10 is a circuit that transfers multiple signals generated in a first domain to a second domain. The first domain and the second domain may be domains having different power supply levels or separate power supplies. The signal isolation circuit 10 may include all or part of a multi-signal encoder 100, a transceiver 120, and a multi-signal decoder 140. The components illustrated in FIG. 1 represent functionally distinct elements, and at least one of the components may be implemented in an integrated form in an actual physical environment.

The multi-signal encoder 100 encodes multiple input signals SCP_HV, TSPWM_HV, and RDY_HV generated in the first domain into a single signal TX_IN.

The encoded signal TX_IN is modulated into a high-frequency signal by a transmitter 122 of the transceiver 120, transmitted to the second domain through an isolation channel (or isolation barrier) 124, and then restored through demodulation by a receiver 126. The transmitter 122 and receiver 126 may modulate and demodulate signals based on an on-off keying (OOK) topology. The isolation channel 124 may employ, but is not limited to, a micro-transformer, capacitors, magneto-resistors/giant magneto-resistors, or opto-electric devices, and the present disclosure does not specify any particular method for implementation thereof.

The multi-signal decoder 140 decodes the demodulated signal RX_OUT into multiple output signals SCP_LV, TSPWM_LV, and RDY_LV.

For the convenience of description, the present disclosure assumes that the first domain is a high-voltage (HV) domain, the second domain is a low-voltage (LV) domain, and the multiple input/output signals include a short-circuit protection signal (SCP signal), an external temperature sensing signal (TSPWM signal), and a power-supply-and-internal-temperature sensing signal (RDY signal). The SCP signal is a short-circuit protection signal of the first domain and may be a signal output from a desaturation (DESAT) protection circuit or an overcurrent protection (OCP) circuit. The TSPWM signal is a square-wave signal representing the temperature of an external switching device, module, or printed circuit board (PCB), and is generated by the pulse-width modulation (PWM) method in which the duty ratio of a signal varies according to the detected temperature. The RDY signal represents the power supply and internal temperature of an integrated circuit. For example, when the power supply and internal temperature are suitable for operation of the integrated circuit, the RDY signal exhibits a logic high level, whereas when the power supply or internal temperature is not suitable for operation of the integrated circuit, the RDY signal exhibits a logic low level.

However, the domains to which the signal isolation circuit 10 according to the present disclosure is applied and the types of input/output signals are not limited to the above examples; it should be noted that the technical principles of the present disclosure may also be applied when different types of signals are to be transferred through a single transceiver between different domains.

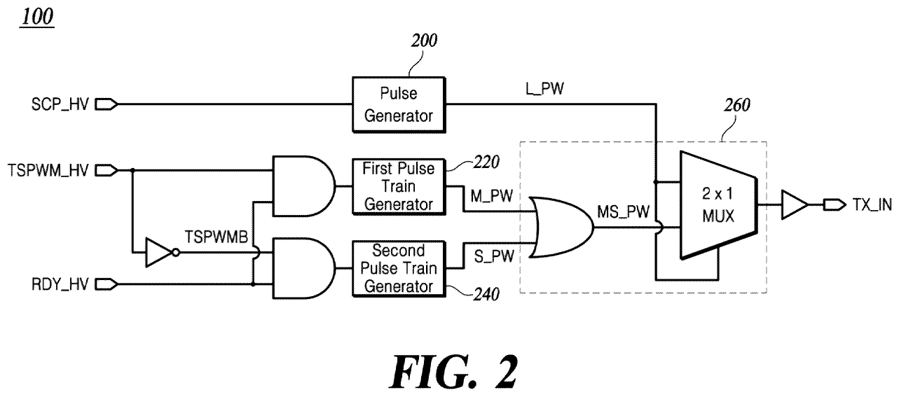

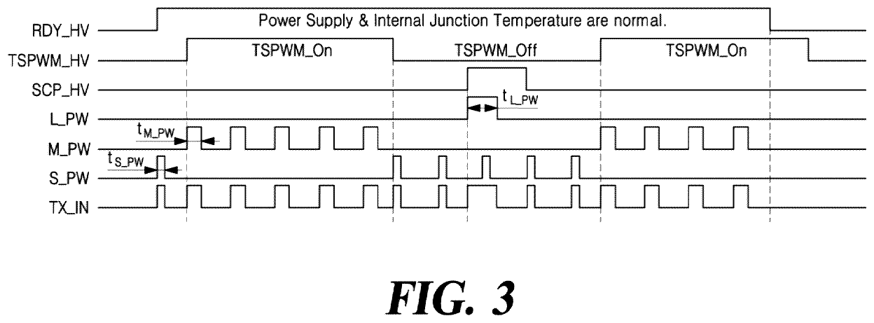

FIG. 2 illustrates a configuration of a multi-signal encoder according to an embodiment of the present disclosure. FIG. 3 is a timing diagram illustrating an operation of a multi-signal encoder according to an embodiment of the present disclosure.

As illustrated in FIG. 2, the multi-signal encoder 100 may include all or part of a pulse generator 200 configured to generate a first pulse signal L_PW based on the SCP signal SCP_HV, a first pulse train generator 220 configured to generate a second pulse signal M_PW based on a combination of the TSPWM signal TSPWM_HV and the RDY signal RDY_HV, a second pulse train generator 240 configured to generate a third pulse signal S_PW based on a combination of the TSPWM signal TSPWM_HV and the RDY signal RDY_HV, and a merging circuit 260 configured to combine the first to third pulse signals L_PW, M_PW, and S_PW into a single signal TX_IN.

The pulse generator 200 may be activated during a time interval in which the SCP signal SCP_HV has a first logic level (e. g., logic high). The first logic level may correspond to a logic level output when a short-circuit is detected. The first pulse signal L_PW may include a single pulse during the time interval in which the SCP signal SCP_HV has the first logic level.

The first pulse train generator 220 may generate the second pulse signal M_PW by detecting an on-pulse of the TSPWM signal TSPWM_HV. For example, the first pulse train generator 220 may be activated during a time interval in which the TSPWM signal TSPWM_HV has a first logic level (e.g., logic high). The number of pulses included in the second pulse signal M_PW may vary according to a length of the on-pulse interval of the TSPWM signal TSPWM_HV.

The second pulse train generator 240 may generate a third pulse signal S_PW by detecting an off-pulse of the TSPWM signal TSPWM_HV. For example, the second pulse train generator 240 may be activated during a time interval in which the TSPWM signal TSPWM_HV has a second logic level (e.g., logic low). The number of pulses included in the third pulse signal S_PW may vary depending on a length of the off-pulse interval of the TSPWM signal TSPWM_HV. The second pulse train generator 240 may be implemented using the same circuit as the first pulse train generator 220 but may receive an inverted TSPWM signal TSPWMB to detect the off-pulse instead of the on-pulse.

The RDY signal RDY_HV may serve to control transmission of the TSPWM signal TSPWM_HV to the second domain. To this end, the TSPWM signal TSPWM_HV and the inverted TSPWM signal TSPWMB may be input to the first pulse train generator 220 and the second pulse train generator 240, respectively, after being AND-gated by the RDY signal RDY_HV. When the RDY signal RDY_HV has a logic low level (i.e., when the power supply or internal temperature is not suitable for operation of the integrated circuit), the operations of the first pulse train generator 220 and the second pulse train generator 240 are disabled, thereby preventing information on the TSPWM signal TSPWM_HV from being transferred to the second domain. In another example, if the RDY signal RDY_HV is implemented to have a logic high level when the power supply or internal temperature is unsuitable for operation, the TSPWM signal TSPWM_HV and the inverted TSPWM signal TSPWMB may be AND-gated by an inverted RDY signal (not shown).

Referring to FIG. 3, the first to third pulse signals L_PW, M_PW, and S_PW may each have different pulse widths. For example, the first pulse signal L_PW may have a first pulse width t_{L_PW} relatively longer than those of the other pulse signals M_PW and S_PW, the second pulse signal M_PW may have a medium-level second pulse width t_{M_PW}, and the third pulse signal S_PW may have a relatively short third pulse width t_{S_PW} compared to those of the other pulse signals L_PW and M_PW.

The merging circuit 260 may OR-gate the second pulse signal M_PW and the third pulse signal to merge them into a single fourth pulse signal MS_PW and may selectively output either the first pulse signal L_PW or the fourth pulse signal MS_PW through a 2×1 multiplexer (MUX). The 2×1 MUX may receive the first pulse signal L_PW as a selection signal. In other words, the signal TX_IN output by the 2×1 MUX may be selected based on the logic level of the first pulse signal L_PW. For example, the 2×1 MUX may output the first pulse signal L_PW during a time interval in which the first pulse signal L_PW has a logic high level and may output the fourth pulse signal MS_PW during a time interval in which the first pulse signal L_PW has a logic low level. In another example, the merging circuit 260 may be implemented as a 3×1 MUX (not shown) configured to selectively output one of the first to third pulse signals L_PW, M_PW, and S_PW. In yet another example, the merging circuit 260 may generate an output signal TX_IN by OR-gating the first pulse signal L_PW and the fourth pulse signal MS_PW.

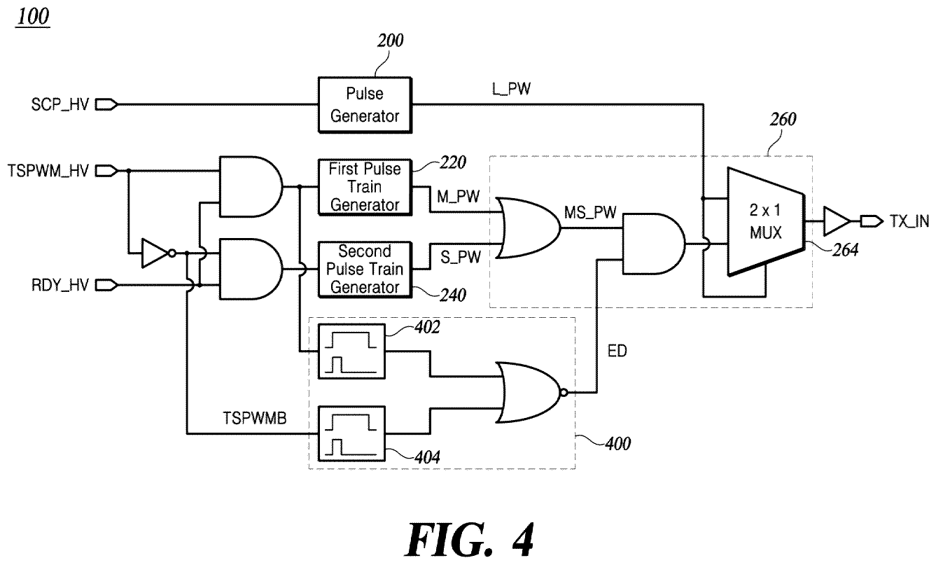

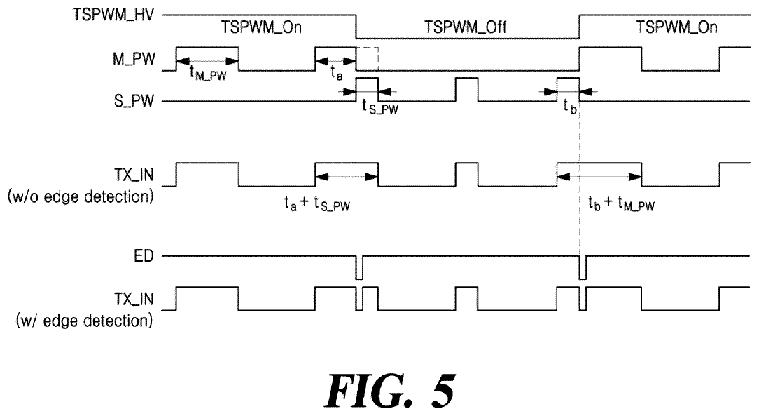

FIG. 4 illustrates a configuration of a multi-signal encoder according to another embodiment of the present disclosure. FIG. 5 is a timing diagram illustrating an operation of a multi-signal encoder according to another embodiment of the present disclosure.

The multi-signal encoder 100 may further include an edge detection circuit 400 configured to generate an edge detection signal ED by detecting edges of the TSPWM signal TSPWM_HV.

The edge detection circuit 400 may include a first detection circuit 402 configured to detect an on-pulse edge (generally, a rising edge) of the TSPWM signal TSPWM_HV and a second detection circuit 404 configured to detect an off-pulse edge (generally, a falling edge) of the TSPWM signal TSPWM_HV. The first detection circuit 402 and the second detection circuit 404 may each be triggered by the on-pulse edge and the off-pulse edge of the TSPWM signal TSPWM_HV, respectively, and may generate a single pulse having a predetermined pulse width. The first detection circuit 402 and the second detection circuit 404 may be implemented, for example, using a combination of delay cells and logic gates, although the present disclosure is not limited to the specific implementation.

Signals output from the first detection circuit 402 and the second detection circuit 404 may be NOR-gated to form the edge detection signal ED. The edge detection signal ED may have a logic low level only for a predetermined period of time from an edge of the TSPWM signal TSPWM_HV and may maintain a logic high level during remaining time intervals.

FIG. 5 illustrates output signals TX_IN that may be generated depending on whether the multi-signal encoder 100 includes the edge detection circuit 400. In the present example, for the simplicity of description, the SCP signal SCP_HV is assumed to be fixed at a logic low level.

Referring to FIG. 5, depending on the length of the on-pulse or off-pulse interval of the TSPWM signal TSPWM_HV, pulses of the second pulse signal M_PW and the third pulse signal S_PW may overlap with each other at edges of the TSPWM signal TSPWM_HV. For example, when an off-pulse edge of the TSPWM signal TSPWM_HV occurs before (or simultaneously with) termination of a pulse of the second pulse signal M_PW and a pulse of the third pulse signal S_PW begins, a pulse having a pulse width tₐ+t_{S_PW} longer than the third pulse width t_{S_PW} may appear in both the fourth pulse signal MS_PW and the output signal TX_IN. Similarly, when an on-pulse edge of the TSPWM signal TSPWM_HV occurs before (or simultaneously with) termination of a pulse of the third pulse signal S_PW and a pulse of the second pulse signal M_PW begins, a pulse having a pulse width t_{b}+t_{M_PW} longer than the second pulse width t_{M_PW} may appear in both the fourth pulse signal MS_PW and the output signal TX_IN. When the pulse width tₐ+t_{S_PW} or t_{b}+t_{M_PW} of an overlapped pulse is longer than the first pulse width t_{L_PW}, the multi-signal decoder 140 described below may incorrectly recognize the edge timing of the TSPWM signal TSPWM_LV as the edge timing of the SCP signal SCP_LV, thereby generating erroneous signals.

To prevent the malfunction above, the multi-signal encoder 100 may use the edge detection signal ED to clearly define boundaries between the on-pulse and off-pulse intervals of the TSPWM signal TSPWM_HV in the fourth pulse signal MS_PW and the output signal TX_IN. The multi-signal encoder 100 may mask the fourth pulse signal MS_PW using the edge detection signal ED. For example, the fourth pulse signal MS_PW may be AND-gated with the edge detection signal ED and then input to the 2×1 MUX 264.

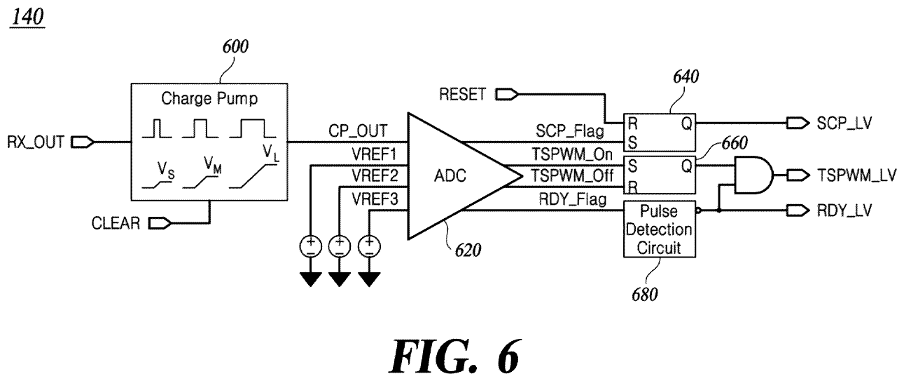

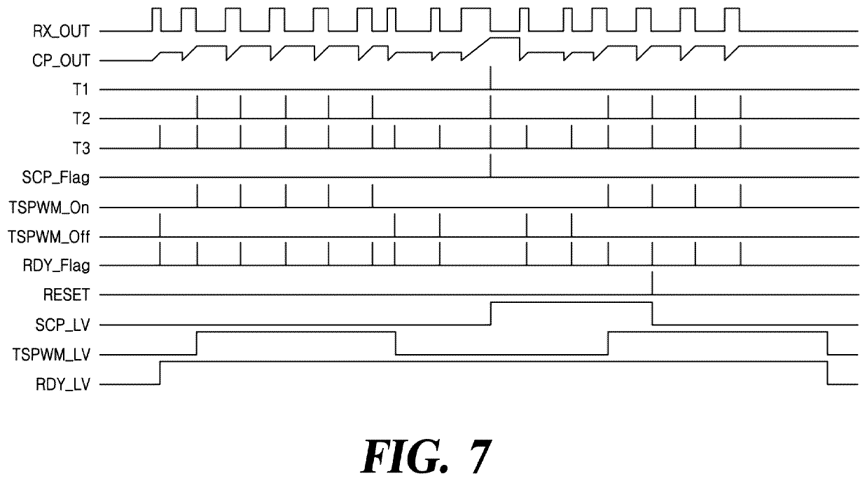

FIG. 6 illustrates a configuration of a multi-signal decoder according to an embodiment of the present disclosure. FIG. 7 is a timing diagram illustrating an operation of a multi-signal decoder according to an embodiment of the present disclosure.

As illustrated in FIG. 6, the multi-signal decoder 140 may include all or part of a charge pump circuit 600, an analog-to-digital converter (ADC) 620, latches 640 and 660, and a pulse detection circuit 680.

The charge pump circuit 600 may generate an analog signal CP_OUT whose potential varies according to the pulse width of an input signal RX_OUT. For example, referring to FIG. 7, the longer the pulse width of an individual pulse in the input signal RX_OUT, the higher the potential of the analog signal CP_OUT. While the structure of any conventional charge pump circuit may be adopted for the charge pump circuit 600, the present disclosure is not limited to a particular structure.

The analog-to-digital converter 620 may convert the analog signal CP_OUT output from the charge pump circuit 600 into a plurality of digital signals SCP_Flag, TSPWM_ON, TSPWM_OFF, and RDY_Flag. The analog-to-digital converter 620 may generate a plurality of digital signals by comparing the analog signal CP_OUT with a plurality of reference voltages VREF1, VREF2, and VREF3. The plurality of digital signals may include a first flag signal SCP_Flag indicating an edge timing (on-pulse or off-pulse) of the SCP signal SCP_LV, a second flag signal TSPWM_ON indicating the on-pulse edge timing of the TSPWM signal TSPWM_LV, a third flag signal TSPWM_OFF indicating the off-pulse edge timing of the TSPWM signal TSPWM_LV, and a fourth flag signal RDY_Flag indicating both the on-pulse and off-pulse edge timings of the TSPWM signal TSPWM_LV. The first flag signal SCP_Flag, the second flag signal TSPWM_ON, and the third flag signal TSPWM_OFF may be expressed as a one-hot code in which only one signal maintains a logic-high level within the same time interval.

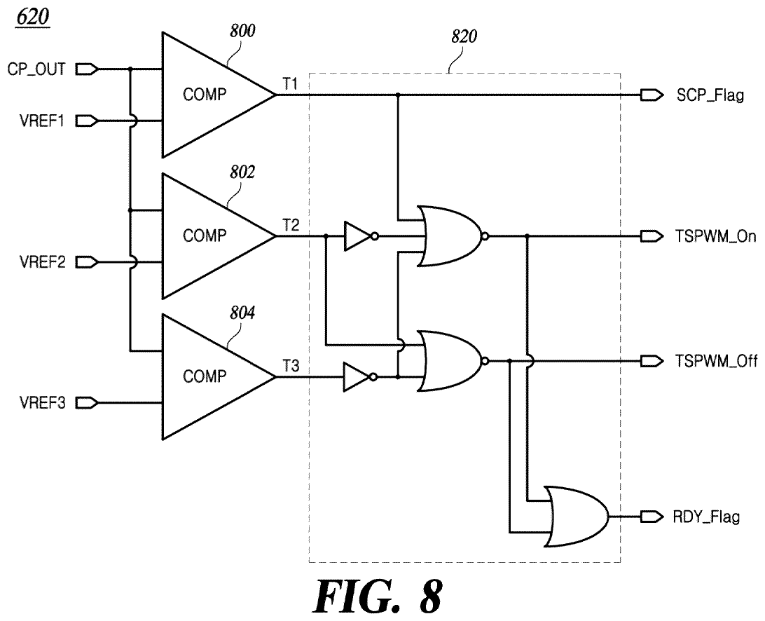

FIG. 8 illustrates a configuration of an analog-to-digital converter according to an embodiment of the present disclosure.

Referring to FIG. 8, the analog-to-digital converter 620 may include a plurality of comparators 800, 802, and 804 and a masking circuit 820.

The comparators 800, 802, and 804 compare the analog signal CP_OUT with each of the reference voltages VREF1, VREF2, and VREF3. For example, a first comparator 800 may compare the analog signal CP_OUT with the first reference voltage VREF1, a second comparator 802 may compare the analog signal CP_OUT with the second reference voltage VREF2, and a third comparator 804 may compare the analog signal CP_OUT with the third reference voltage VREF3.

The first reference voltage VREF1 may be set by considering the length of the first pulse width t_{L_PW} and a predetermined margin; the second reference voltage VREF2 may be set by considering the length of the second pulse width t_{M_PW} and a predetermined margin; and the third reference voltage VREF3 may be set by considering the length of the third pulse width t_{S_PW} and a predetermined margin. For example, the first reference voltage VREF1 may have the highest voltage, and the third reference voltage VREF3 may have the lowest voltage.

The outputs T1 to T3 of the comparators 800, 802, and 804 may be represented using a thermometer code. For example, when the analog signal CP_OUT has a voltage higher than the first reference voltage VREF1, the outputs T1 to T3 of the first to third comparators may all have a logic high level. In another example, when the analog signal CP_OUT has a voltage lower than the first reference voltage VREF1 but higher than the second reference voltage VREF2, the output T1 of the first comparator may have a logic low level, and the outputs T2 and T3 of the second and third comparators may have logic high levels. In yet another example, when the analog signal CP_OUT has a voltage lower than the second reference voltage VREF2 but higher than the third reference voltage VREF3, the outputs T1 and T2 of the first and second comparators may have logic low levels, and the output T3 of the third comparator may have a logic high level. In still another example, when the analog signal CP_OUT has a voltage lower than the third reference voltage VREF3, the outputs T1 to T3 of the first to third comparators may all have logic low levels. The comparators 800, 802, and 804 may be enabled at a falling edge of the input signal RX_OUT. Each of the comparators 800, 802, and 804 may be reset by its own output T1 to T3.

The masking circuit 820 converts the outputs T1 to T3 of the first to third comparators 800, 802, and 804, which are expressed as a 3-bit thermometer code, into first to third flag signals SCP_Flag, TSPWM_ON, and TSPWM_OFF expressed as a 3-bit one-hot code.

For example, the first flag signal SCP_Flag may directly use the first comparator output T1, the second flag signal TSPWM_ON may be generated by NOR-gating the first comparator output T1, the inverted version of the second comparator output T2, and the inverted version of the third comparator output T3, and the third flag signal TSPWM_OFF may be generated by NOR-gating the output T2 of the second comparator, and the inverted version of the output T3 of the third comparator. Accordingly, as illustrated in FIG. 7, when a pulse having a pulse width longer than a first threshold pulse width appears in the input signal RX_OUT, the first flag signal SCP_Flag may have a logic high level; when a pulse having a pulse width shorter than the first threshold pulse width but longer than a second threshold pulse width appears in the input signal RX_OUT, the second flag signal TSPWM_ON may have a logic high level; when a pulse having a pulse width shorter than the second threshold pulse width but longer than a third threshold pulse width appears in the input signal RX_OUT, the third flag signal TSPWM_OFF may have a logic high level. Here, the first to third threshold pulse widths may have values determined according to the first to third reference voltages VREF1, VREF2, and VREF3 and/or a voltage-boost ratio of the charge pump circuit 600.

Meanwhile, a fourth flag signal RDY_Flag may be generated by OR-gating the second flag signal TSPWM_ON and the third flag signal TSPWM_OFF. Accordingly, as illustrated in FIG. 7, when a pulse having a pulse width shorter than the first threshold pulse width but longer than the third threshold pulse width appears in the input signal RX_OUT, the fourth flag signal RDY_Flag may have a logic high level.

Referring again to FIG. 6, each output of the analog-to-digital converter 620 may be input to one of a first latch 640, a second latch 660, and a pulse detection circuit 840. For example, among the 3-bit one-hot codes generated by the masking circuit 820, the first flag signal SCP_Flag corresponding to the most significant bit may be input to the first latch 640, and the second and third flag signals TSPWM_ON and TSPWM_OFF corresponding to the remaining lower bits may be input to the second latch 660. Also, the fourth flag signal RDY_Flag, which corresponds to the logical OR of the lower bits, may be input to the pulse detection circuit 840.

The first latch 640 may generate an SCP signal SCP_LV based on timing indicated by the first flag signal SCP_Flag. The first latch 640 may be an RS latch. The first latch 640 may receive the first flag signal SCP_Flag as a set input or reset input. For example, referring to FIG. 7, the SCP signal SCP_LV may be set by the first flag signal SCP_Flag and reset by a reset signal RESET input from the outside.

The second latch 660 may generate a TSPWM signal TSPWM_LV based on timing indicated by the second flag signal TSPWM_ON and the third flag signal TSPWM_OFF. The second latch 660 may be an RS latch. The second latch 660 may receive the second flag signal TSPWM_ON and the third flag signal TSPWM_OFF as set or reset inputs, respectively. For example, referring to FIG. 7, the TSPWM signal TSPWM_LV may be set by the second flag signal TSPWM_ON and reset by the third flag signal TSPWM_OFF. The TSPWM signal TSPWM_LV may be generated by AND-gating the output signal of the second latch 660 with the RDY signal RDY_LV.

The pulse detection circuit 840 may output an RDY signal RDY_LV having a logic low level when the fourth flag signal RDY_Flag is not applied for a time longer than a predetermined time.

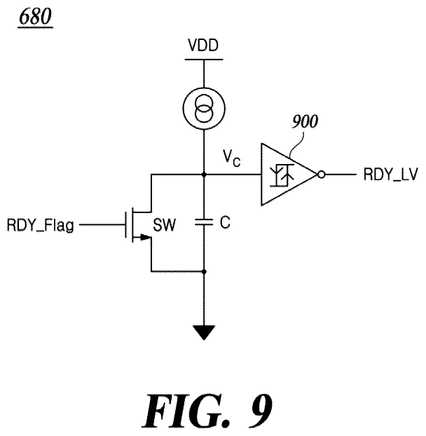

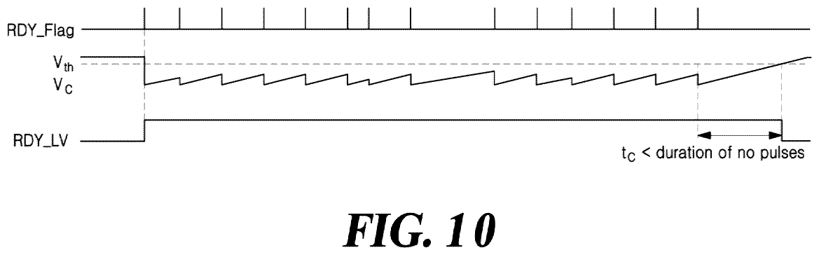

FIG. 9 illustrates a configuration of a pulse detection circuit according to an embodiment of the present disclosure. FIG. 10 is a waveform diagram illustrating an operation of a pulse detection circuit according to an embodiment of the present disclosure.

Referring to FIG. 9, the pulse detection circuit 840 according to an embodiment of the present disclosure may include all or part of a switching element SW, a capacitor C, and a hysteresis comparator 900. In an ordinary operation state in which the fourth flag signal RDY_Flag is not applied, the capacitor C is charged by a power supply; when the fourth flag signal RDY_Flag is applied, the capacitor C is discharged as the switching element SW is turned on. The hysteresis comparator 900 may output an RDY signal RDY_LV having a logic low level when a voltage V_{C} of the capacitor C increases above a predetermined threshold voltage. For example, referring to FIG. 10, when the fourth flag signal RDY_Flag is repeatedly applied at predetermined intervals, the capacitor C is repeatedly discharged, and the voltage V_{C} of the capacitor C may be maintained below the threshold voltage Vₜₕ. On the other hand, when the fourth flag signal RDY_Flag is not applied for a time longer than a predetermined time t_{C}, the voltage V_{C} of the capacitor C may increase above the threshold voltage Vₜₕ.

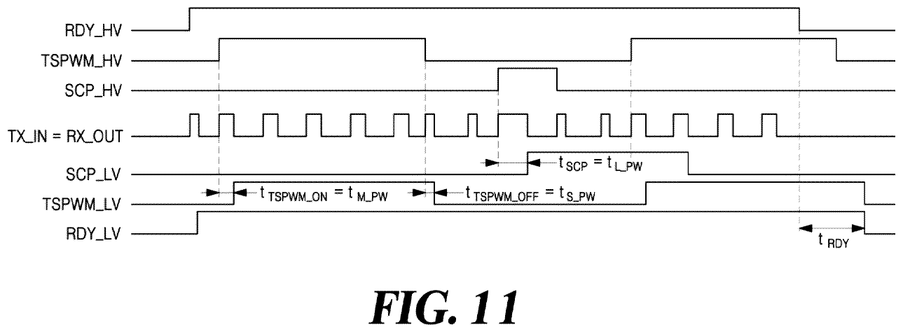

FIG. 11 is a waveform diagram illustrating multiple input signals and multiple output signals of a signal isolation circuit according to an embodiment of the present disclosure.

Referring to FIG. 11, assuming that a delay time caused by the operation of the transceiver 120 is negligibly small, a delay time t_{SCP} between the SCP signal SCP_HV of the first domain and the SCP signal SCP_LV of the second domain is based on the first pulse width t_{L_PW}; a delay time t_{TSPWM_ON} between the on-pulse of the TSPWM signal TSPWM_HV of the first domain and the on-pulse of the TSPWM signal TSPWM_LV of the second domain is based on the second pulse width t_{M_PW}; and a delay time t_{TSPWM_OFF} between the off-pulse of the TSPWM signal TSPWM_HV of the first domain and the off-pulse of the TSPWM signal TSPWM_LV of the second domain is based on the third pulse width t_{S_PW}.

As described above, the multi-signal encoder 100 according to various embodiments of the present disclosure assigns different pulse widths to the SCP signal SCP_HV, the on-pulse of the TSPWM signal TSPWM_HV, and the off-pulse of the TSPWM signal TSPWM_HV and encode them into a single output signal TX_IN, and the multi-signal decoder 140 may decode the SCP signal SCP_LV and the TSPWM signal TSPWM_LV from the input signal RX_OUT based on the pulse widths of the individual pulses included in the input signal RX_OUT. Also, when the RDY signal in the first domain has a first logic level (e.g., logic high), the multi-signal encoder 100 may transfer a series of pulses (e.g., pulses having designated pulse widths corresponding to the on-pulse and off-pulse of the TSPWM signal TSPWM_HV) to the second domain; when the RDY signal has a second logic level (e.g., logic low), the multi-signal encoder 100 may not transfer the corresponding pulse train to the second domain. The multi-signal decoder 140 may decode the RDY signal RDY_LV by recognizing whether or not the corresponding pulse trains have been received.

Various embodiments of systems and techniques described herein can be realized with analog electronic circuits, digital electronic circuits, integrated circuits, field programmable gate arrays (FPGAs), application specific integrated circuits (ASICs), and/or combinations thereof.

According to an embodiment of the present disclosure, multiple signals may be transferred through a single isolation channel with minimum chip area and minimum power consumption. In a conventional signal isolation circuit, up to four and at least two transceiver circuits are required to transmit three types of multiple signals, whereas a signal isolation circuit according to the present disclosure is capable of transmitting three types of multiple signals using only one transceiver circuit. Accordingly, chip area and power consumption of the integrated circuit may be reduced, thereby achieving the effect of lowering manufacturing costs.

The features of the present disclosure are not limited to the features described above, and other features not mentioned herein may be understood to those skilled in the art to which the present disclosure belongs from the description above.

Although exemplary embodiments of the present disclosure have been described for illustrative purposes, those skilled in the art will appreciate that various modifications, additions, and substitutions are possible, without departing from the idea and scope of the claimed invention. Therefore, exemplary embodiments of the present disclosure have been described for the sake of brevity and clarity. The scope of the technical idea of the present embodiments is not limited by the illustrations. Accordingly, one of ordinary skill would understand that the scope of the claimed invention is not to be limited by the above explicitly described embodiments but by the claims and equivalents thereof.

What is claimed is

1. A signal isolation circuit for transferring multiple signals from a first domain to a second domain, the signal isolation circuit comprising:
a multi-signal encoder configured to encode first to third signals of the first domain into a single fourth signal, wherein the multi-signal encoder is configured to adjust a pulse width of the fourth signal of the first domain based on the first and second signals of the first domain, and control whether to generate a pulse corresponding to the second signal of the first domain based on a third signal of the first domain;
a transceiver configured to transfer the fourth signal from the first domain to the second domain; and
a multi-signal decoder configured to decode the first to third signals from the fourth signal in the second domain, wherein the multi-signal decoder is configured to generate the first and second signals of the second domain based on a pulse width of the fourth signal of the second domain, and generate a third signal of the second domain based on a time interval between pulses of the fourth signal of the second domain.

2. The signal isolation circuit of claim 1, wherein the multi-signal encoder comprises:
a pulse generator configured to generate, based on the first signal of the first domain, a first pulse signal having a first pulse width;
a first pulse train generator configured to generate, based on the second signal of the first domain having a first logic level. a second pulse signal having a second pulse width different from the first pulse width, wherein the first pulse train generator is configured to be selectively disabled based on a logic level of the third signal of the first domain;
a second pulse train generator configured to generate, based on the second signal of the first domain having a second logic level, a third pulse signal having a third pulse width different from the first and second pulse widths, wherein the second pulse train generator is configured to be selectively disabled based on the logic level of the third signal of the first domain; and
a merging circuit configured to generate the fourth signal of the first domain by merging the first, second, and third pulse signals.

3. The signal isolation circuit of claim 2, wherein:
the pulse generator generates the first pulse signal having a single pulse during a time interval in which the first signal of the first domain has the first logic level,
the first pulse train generator generates the second pulse signal having one or more pulses according to a length of a time interval during which the second signal of the first domain has the first logic level, and
the second pulse train generator generates the third pulse signal having one or more pulses according to a length of a time interval during which the second signal of the first domain has the second logic level.

4. The signal isolation circuit of claim 2, wherein:
the second pulse width is smaller than the first pulse width, and
the third pulse width is smaller than the second pulse width.

5. The signal isolation circuit of claim 2, wherein the merging circuit includes:
a logic gate configured to merge the second pulse signal and the third pulse signal; and
a multiplexer configured to output, as the fourth signal of the first domain, one of the first pulse signal and the merged signal based on the first pulse signal.

6. The signal isolation circuit of claim 5, wherein:
the multi-signal encoder further includes an edge detection circuit configured to generate an edge detection signal by detecting rising and falling edges of the second signal of the first domain, and
the merged signal is masked by the edge detection signal.

7. The signal isolation circuit of claim 1, wherein:
the multi-signal decoder includes a pulse detection circuit configured to generate the third signal of the second domain
the pulse detection circuit generates the third signal of the second domain based on whether a subsequent pulse occurs within a time, defined by a design of the detection circuit, from a time point when a preceding pulse occurs in the fourth signal of the second domain.

8. The signal isolation circuit of claim 1, wherein the multi-signal decoder includes:
a first latch configured to generate the first signal of the second domain based on a time point when a first pulse having a length longer than a first threshold pulse width is detected in the fourth signal of the second domain; and
a second latch configured to generate the second signal of the second domain based on both a time point when a second pulse having a length shorter than the first threshold pulse width and longer than a second threshold pulse width is detected and a time point when a third pulse having a length shorter than the second threshold pulse width and longer than a third threshold pulse width is detected in the fourth signal of the second domain.

9. The signal isolation circuit of claim 8, wherein
the first latch receives, as a set input or a reset input, a first flag signal having an edge formed corresponding to the time point when the first pulse is detected, and
the second latch receives, as either a set input or a reset input respectively, a second flag signal having an edge formed corresponding to the time point when the second pulse is detected and a third flag signal having an edge formed corresponding to the time point when the third pulse is detected.

10. The signal isolation circuit of claim 8, wherein:
the multi-signal decoder further includes:
a charge pump circuit configured to convert the fourth signal of the second domain into a signal having a potential corresponding to a pulse width; and
an analog-to-digital converter configured to generate one-hot codes by comparing the potential of the converted signal with a plurality of reference potentials,
the first latch receives the most significant bit of the one-hot code, and
the second latch receives remaining bits excluding the most significant bit.

11. The signal isolation circuit of claim 10, wherein the analog-to-digital converter includes:
a plurality of comparators configured to generate a thermometer code by comparing a potential of the converted signal with each of the plurality of reference potentials; and
a masking circuit configured to convert the thermometer code into the one-hot code.

12. The signal isolation circuit of claim 1, wherein:
the first signal of the first domain is a short-circuit protection signal (SCP) output from a short-circuit protection circuit provided in the first domain,
the second signal of the first domain is a signal obtained by pulse width modulation (PWM) based on a temperature detected from an external switching element, a module, or a printed circuit board (PCB), and
the third signal of the first domain is a power-supply-and-internal-temperature sensing signal (RDY) indicating whether a power supply and an internal temperature of the first domain are in a normal operation state.

13. A multi-signal encoder for encoding multiple input signals into a single output signal, the multi-signal encoder comprising:
a pulse generator configured to generate, based on a first input signal, a first pulse signal having a first pulse width;
a first pulse train generator configured to generate, based on a second input signal having a first logic level, a second pulse signal having a second pulse width different from the first pulse width, wherein the first pulse train generator is configured to be selectively disabled based on a logic level of a third input signal;
a second pulse train generator configured to generate, based on the second input signal having a second logic level, a third pulse signal having a third pulse width different from the first and second pulse widths, wherein the second pulse train generator is configured to be selectively disabled based on a logic level of the third input signal; and
a merging circuit configured to generate the output signal by merging the first, second, and third pulse signals.

14. The multi-signal encoder of claim 13, wherein:
the pulse generator generates the first pulse signal having a single pulse during a time interval in which the first input signal has the first logic level,
the first pulse train generator generates the second pulse signal having one or more pulses according to a length of a time interval during which the second input signal has the first logic level, and
the second pulse train generator generates the third pulse signal having one or more pulses according to a length of a time interval during which the second input signal has the second logic level.

15. The multi-signal encoder of claim 13, wherein:
the second pulse width is smaller than the first pulse width, and
the third pulse width is smaller than the second pulse width.

16. The multi-signal encoder of claim 13, wherein the merging circuit includes:
a logic gate configured to merge the second pulse signal and the third pulse signal; and
a multiplexer configured to output, as the fourth signal of the first domain, one of the first pulse signal and the merged signal based on the first pulse signal.

17. A multi-signal decoder for decoding a single input signal into multiple output signals, the multi-signal decoder comprising:
a first latch configured to generate a first output signal based on a time point when a first pulse having a length longer than a first threshold pulse width is detected in the input signal;
a second latch configured to generate a second output signal based on both a time point when a second pulse having a length shorter than the first threshold pulse width and longer than a second threshold pulse width and a time point when a third pulse having a length shorter than the second threshold pulse width and longer than a third threshold pulse width are detected in the input signal; and
a pulse detection circuit configured to generate a third output signal based on time interval between pulses in the input signal,
wherein the pulse detection circuit generates the third output signal based on whether a subsequent pulse occurs within a time, defined by a design of the detection circuit, from a time point when a preceding pulse occurs in the input signal.

18. The multi-signal decoder of claim 17, wherein:
the first latch receives, as a set input or a reset input, a first flag signal having an edge formed corresponding to the time point when the first pulse is detected, and
the second latch receives, as either a set input or a reset input respectively, a second flag signal having an edge formed corresponding to the time point when the second pulse is detected and a third flag signal having an edge formed corresponding to the time point when the third pulse is detected.

19. The multi-signal decoder of claim 17, further comprising:
a charge pump circuit configured to convert the input signal into a signal having a potential corresponding to a pulse width; and
an analog-to-digital converter configured to generate one-hot codes by comparing the potential of the converted signal with a plurality of reference potentials,
wherein the first latch receives the most significant bit of the one-hot code, and
the second latch receives remaining bits excluding the most significant bit.

20. The multi-signal decoder of claim 19, wherein the analog-to-digital converter includes:
a plurality of comparators configured to generate a thermometer code by comparing a potential of the converted signal with each of the plurality of reference potentials; and
a masking circuit configured to convert the thermometer code into the one-hot code.
